(19) United States
(12) Patent Application Publication
(10) Pub. No.: US 2010/0200775 A1
(43) Pub. Date: Aug. 12, 2010

(54) Real Time Monitoring Ion Beam

(76) Inventors: Wei-Cheng Lin, Hsinchu (TW); Nai-Yuan Cheng, Taipei (TW)

Correspondence Address: STOUT, UXA, BUYAN & MULLINS LLP, 4 VENTURE, SUITE 300, IRVINE, CA, 92618, US

(21) Appl. No.: 12/370,571

(22) Filed: Feb. 12, 2009

(51) Int. Cl. H01J 37/08

(52) U.S. Cl. 250/492.21

(57) ABSTRACT

Deflections from a desired trajectory of an ion beam outputted from an analyzer magnet are corrected with real-time monitoring of the ion beam deflection. Conductive structures are located close to the boundary of the beam exit, where each conductive structure is electrically insulated from other conductive structures and the analyzer magnet. Then, during implantation of ions into a wafer, continuous measuring of any current appearing on each conductive structure occurs, such that any collision between the conductive structure(s) and the ion beam is real-time monitored. By properly adjusting the shape/location/number of the conductive structure(s), and by properly adjusting the relative geometric relation among the conductive structure(s) and the desired trajectory, both the deflected angle and the deflected direction can be real-time monitored. Hence, the on-going implantation process and the implanter can be adjusted/maintained.

### BACKGROUND OF THE INVENTION

1. Field of the Invention

The present invention generally relates to an ion implanter, and more particularly, relates to accomplishing ion beam steering control by comparing offset ion beam currents generated from ions striking an analyzer magnet.

2. Description of the Prior Art

Ion implantation is widely used in the semiconductor manufacture, for example, to implant wafers with desired ions of desired energy. Ion implantation usually requires a uniform distribution and consistent amount of ions beam to be implanted into a wafer.

FIG. 1A is a diagram for a conventional ion implanter 100. The conventional ion implanter 100 can implant specific ions with desired energy on a wafer 20. The ion implanter 100 has an ion source 110 capable of generating an ion beam 10. The ion beam 10 generated from the ion source 110 is analyzed by an analyzer magnet 120 and travels along a desired trajectory. The analyzer magnet 120 includes a beam exit 121, a beam entrance 122 and a magnetic field space 123. Herein, as well-known knowledge, the magnetic filed in the magnetic field space 123 is adjustable. Hence, ions with undesired mass and/or undesired energy strike on the shell of the analyzer magnet 120, and then are removed from the ion beam 10. After that, the ion beam 10 passes through the beam exit 121 and can be projected on the wafer 20. Further, as usual, the ion beam current implanted on the wafer 20 is measured by a Faraday cup which is set close to the position of the wafer 20, or by analyzing the implanted result of wafer 20.

Significantly, in an ideal world, the ion beam 10 always is projected along the desired trajectory, except only ions with undesired energy and/or undesired mass will collide with the analyzer magnet 120. However, in the real world, the ion beam 10 might somehow deviate from the desired trajectory. There are many reasons, for example, the working voltage of the ion source 110 may be unstable, the extraction voltage for extracting ion beam 10 may be floated, and the device for forming a magnetic field inside the analyzer magnet 120 may be too complicated to be precisely controlled/maintained.

The deflection of the ion beam 10 unavoidably changes the incident angle of the ion beam 10 on the wafer 20, such that the distribution of implanted ions in the wafer 20 is changed. Moreover, when the deflection degree is increased, the ion beam 10 might collide with the analyzer 120. The collision between the ion beam 10 and the analyzer magnet 120 unavoidably induces a loss of ions. Therefore, the real implantation on the wafer 20 is different than a predetermined implantation based on the last measured ion beam current.

However, because the implanted ion beam current is measured by the Faraday cup or the implanted result, it is incapable of monitoring the real-time condition of the ion beam, for instance, ion beam injection direction to the wafer 20, before or during the ion implantation process. Therefore, the difference between the real implantation and the predetermined implantation cannot be eliminated immediately.

Clearly, for any real ion implanter, the above disadvantage always is possible. Although the risk can be minimized by adjusting the desired trajectory of the ion beam to be vertical to the beam exit of the analyzer magnet, the risk is increased when the ion source 110 and/or the analyzer magnet 120 is complicated or not properly maintained.

Furthermore, the above disadvantage is more serious for some ion implanters capable of operating over a larger energy range. As shown in FIG. 1B, some ion implanters deflect the ion beam 10 when the ion beam 10 leaves the analyzer magnet 120 and use a tuner 130 to adjust the ion beam 10 after the analyzer magnet 120. Herein, the tuner 130 has an energy portion 131 for tuning the energy of the ion beam 10 by applying at least one electric field and a direction portion 132 for tuning the direction of the ion beam 10 by applying at least one magnetic field and/or one electric filed. The reason to tune the direction is to avoid at least the exit of undesired ions with undesired energy and/or natural particles, which cannot be properly adjusted by the energy portion 131.

Therefore, if the design of the implanter requires that the ion beam 10 may pass through a path close to the boundary of the beam exit 121 (such as the design shown in FIG. 1B), it is easier to have a significant loss of ion beam 10 due to a collision between at least a portion of the ion beam 10 and the analyzer magnet 120. The collision may be induced by improperly controlled deflection, non-ideal ion source 100, or non-ideal analyzer magnet 120.

For the disadvantages mentioned above, there is a need to propose a novel and useful approach for monitoring the real-time condition of the ion beam during the ion implantation process.

### SUMMARY OF THE INVENTION

The present invention provides a new approach for monitoring the real-time condition of the ion beam, and also for steering the ion beam by comparing offset beam (e.g., ion beam) currents generated from hits on (e.g., ions striking) an analyzer magnet.

One embodiment is an ion implanter. The ion implanter comprises an ion source, an analyzer magnet and a measuring device. The analyzer magnet has a shell enclosing a magnetic field space, and both a beam entrance and a beam exit allowing the ion beam to pass through. The analyzer magnet further has at least one conductive structure located close to the boundary of the beam exit and electrically insulated from the shell. Further, each conductive structure is electrically coupled with a measuring device for real-time monitoring of a current produced by a collision between the conductive structure(s) and a deflected ion beam. Hence, ion beam steering control can be achieved by comparing the offset ion beam currents generated from ions striking the analyzer magnet.

Another embodiment is a method for monitoring the real-time real condition of the ion beam. The method comprises the following steps: first, provide an ion beam that passes through a beam exit of an analyzer magnet; second, measure a current that appears on at least one conductive structure located close to the boundary of the beam exit, wherein each conductive structure is electrically insulated from other portions of the analyzer magnet (includes other conductive structure(s)). Then, by real-time analyzing the current, the deflection of the ion beam is real-time monitored whereby the implanter then can be adjusted to adjust the deflection of the ion beam.

### BRIEF DESCRIPTION OF THE DRAWINGS

FIG. 1A is a diagram of a conventional ion implanter;

FIG. 1B is a diagram of another conventional ion implanter;

FIG. 2A shows a sectional view of an ion implanter in accordance with an embodiment of the present invention;

FIG. 2B to FIG. 2D show sectional views of the ion implanters in accordance with some embodiments of the present invention;

FIG. 2E to FIG. 2G show front views of the ion implanter in accordance with some embodiments of the present invention; and

FIG. 3 shows a flowchart of a method in accordance with another embodiment of the present invention.

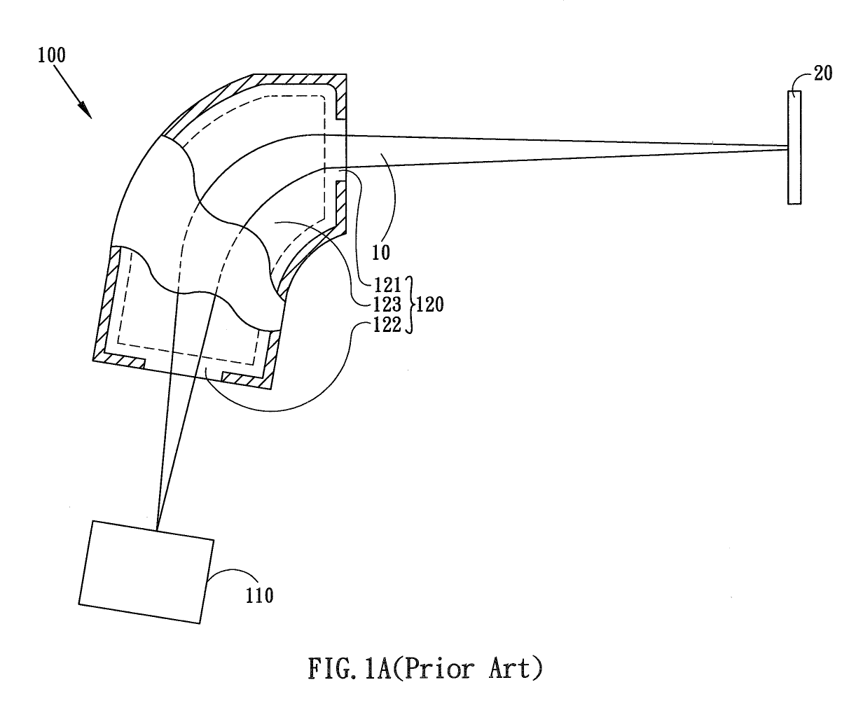

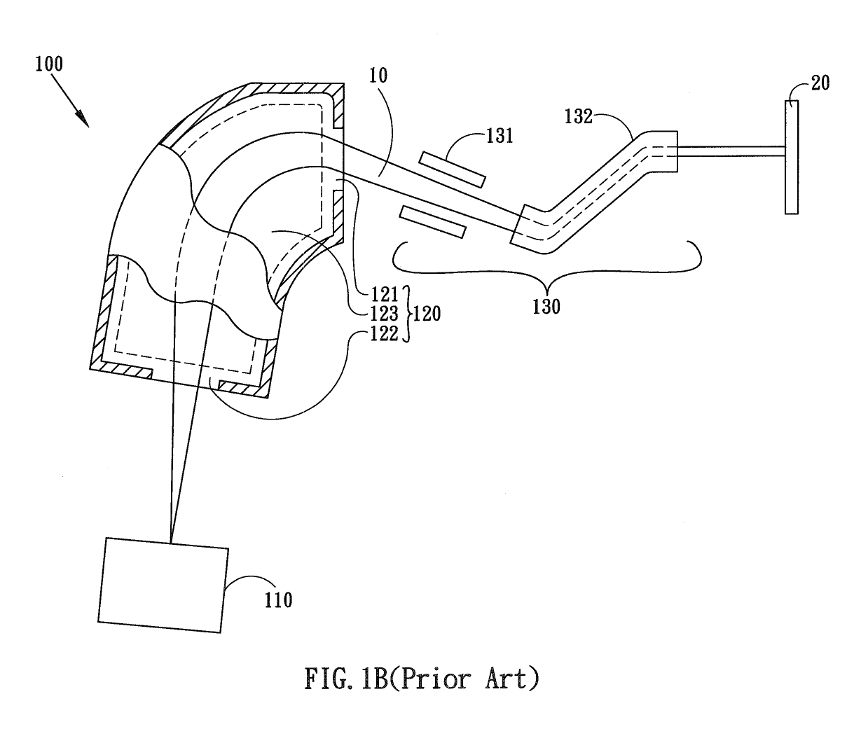

### DETAILED DESCRIPTION OF THE INVENTION

A detailed description of the present invention will be discussed in the following embodiments, which are not intended to limit the scope of the present invention and which can be adapted for other applications. While the drawings are illustrated in detail, it is appreciated that the quantity of the disclosed components may be greater or less than that disclosed, except for where numbers of such components are expressly restricted.

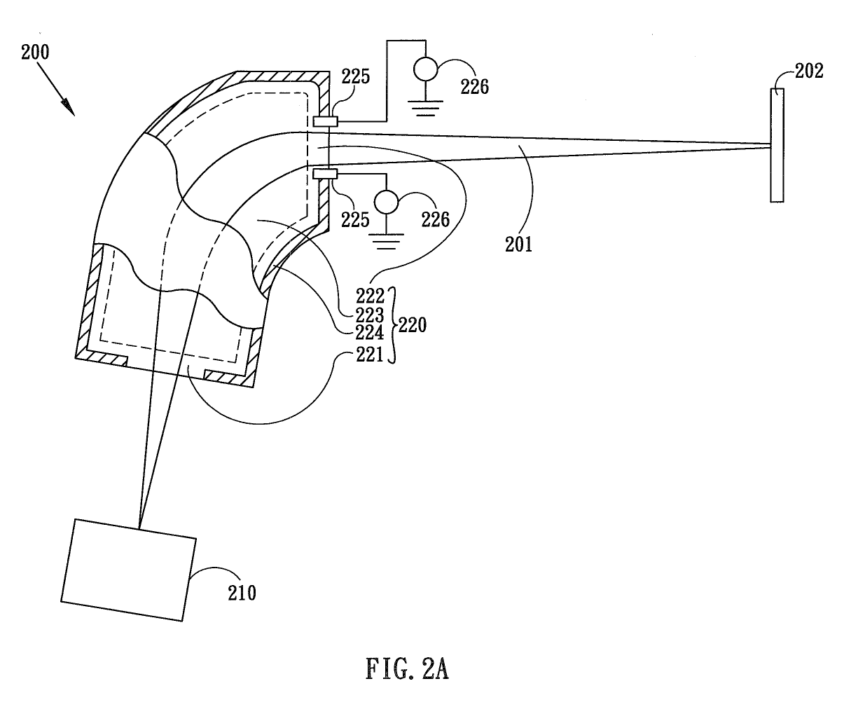

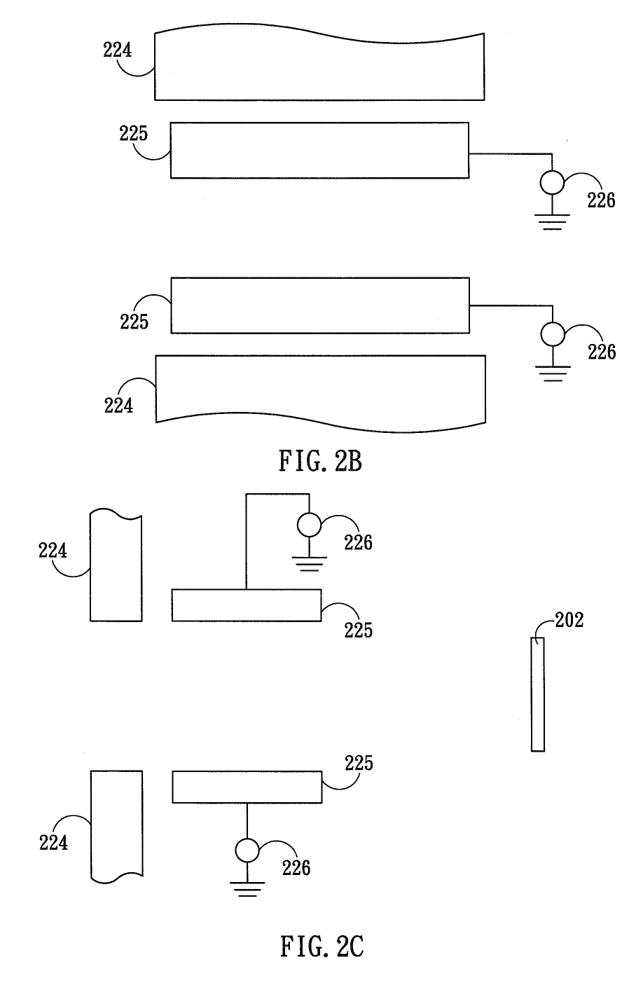

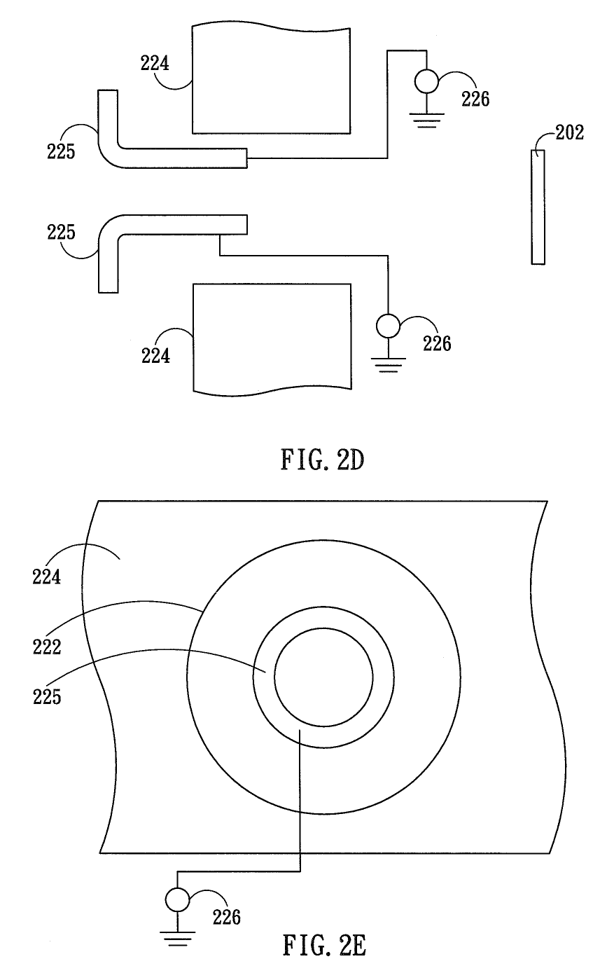

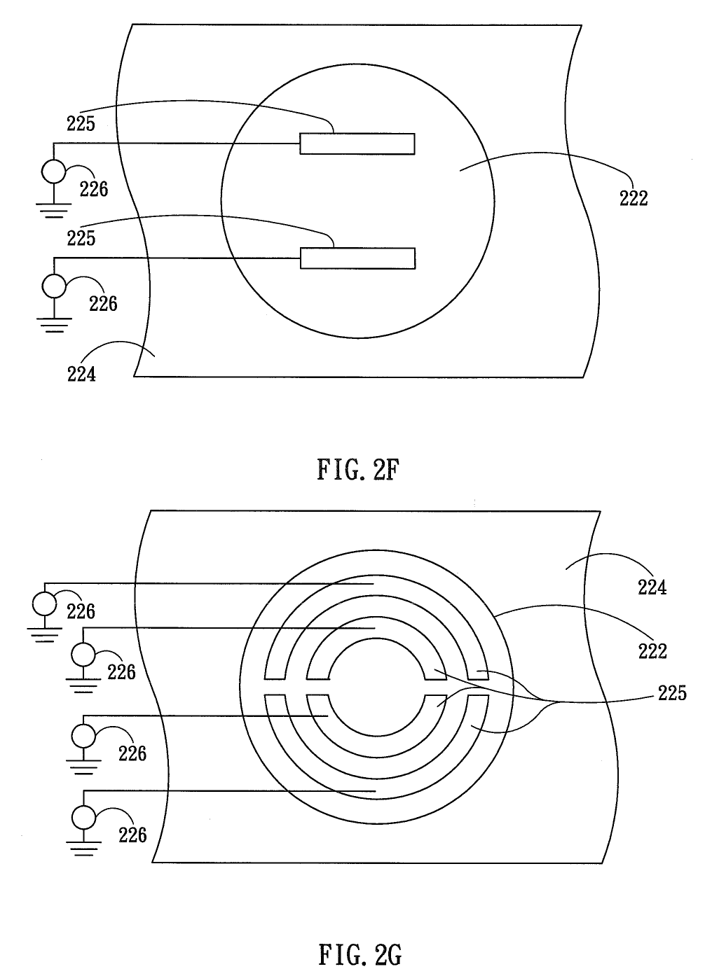

FIG. 2A shows a sectional view of an ion implanter 200 in accordance with an embodiment of the present invention. The implanter 200 includes an ion source 210 and an analyzer magnet 220, and can further include an optional tuner (not shown). The ion beam 201 is generated by the ion source 210 and then adjusted by the analyzer magnet 220. The optional tuner is capable of tuning the ion beam 201, such as to tune the energy and/or the direction of the ion beam 201. Herein, the details of both the ion source 210 and optional tuner are not the characteristics of the invention. Any well-known, existent, on-developing or to-be appeared (e.g., future) ion source and tuner can be used by this invention.

The analyzer magnet 220 includes a beam entrance 221, a beam exit 222, a magnetic field region 223, and a shell 224. The beam entrance 221 faces the ion source 210 and the beam exit 222 faces the wafer 202. The ion beam 201 passes through the beam entrance 221 into the analyzer magnet 220, and then passes through the beam exit 222 toward the wafer 202 along a desired trajectory in an ideal condition. The magnetic field region 223 is essentially located in the middle of the analyzer magnet 220, when the beam entrance 221 and beam exit 222 are located on two different portions of the analyzer magnet 220. Further, the analyzer magnet 220 has at least one conductive structure 225 located close to the boundary of the beam exit 222. Herein, each conductive structure 225 is electrically insulated from the shell 224 and other conductive structure(s) 225 by an electrical insulator (not shown to simplify the figures). Each conductive structure 225 is electrically coupled with a measuring device 226, which can be, for example, a current meter, such that any current appearing on any conductive structure 225 is real-time monitored.

As discussed above, in the real world, the ion beam 201 might somehow deviate from the desired trajectory. Sometimes, the deflection of the ion beam 201 is very slight and then only the incident angle on the wafer 202 is changed. Other times, the deflection of the ion beam 201 is large enough such that the deflected ion beam 201 will collide with the analyzer magnet 120 or other hardware(s) before it is projected into the wafer 202.

Therefore, by properly adjusting the location/shape/number of the conductive structure(s) 225, it is highly possible that the deflected ion beam 201 will only collide with the wafer 202 and/or the conductive structure(s) 225. In other words, by properly adjusting the location/shape/number of the conductive structure(s) 225, the conductive structure(s) 225 can continuously measure current induced by the deflected the ion beam 201, and then provide real-time messages/information on (e.g., about) the deflection of the ion beam 201.

In general, the ion beam 201 is first measured by using the Faraday cup and/or analyzing the implanted result. Hence, an original ion beam current lo is measured. Then, during ion implantation, when the conductive structure(s) 225 catches a deflected ion beam current I_{D} induced by deflected ion beam 201, it is clear that the real implanted ion beam current on the wafer 202 has changed from I₀ to a difference between I₀ and I_{D}. Hence, owing to the measuring device(s) being electrically coupled with the conductive structure(s) 225 continuous monitoring or display of the amount of the I_{D} can be achieved, and the real implanted ion beam current, I₀−I_{D}, can be real-time monitored. Accordingly, the implantation process can be adjusted. For example, the ion source 210 can be adjusted to adjust the amount of the ion beam 201 just generated, the scan path of the ion beam 201 can be adjusted to adjust the implanted result, and/or the implantation period can be extended to balance the decrement of the real implanted ion beam current.

Furthermore, the deflected ion beam current ID is a function of the deflected angle from the desired trajectory. Therefore, the conductive structures 225 can be used to measure the deflected angle of the deflected ion beam 201. In such situations, there are some conductive structures 225 separately located around the desired trajectory. Therefore, for different deflected angles, the deflected ion beam 201 may collide with different conductive structure(s) 225. After that, by continuously measuring different ion beam currents collected by different conductive structures 225, the deflection of the ion beam 201 can be real-time monitored. Without doubt, use of more conductive structures 225 can facilitate more precise measuring of the deflection of the ion beam 201. Accordingly, the operation of the ion implanter 200 can be adjusted, and the ion implanter 200 can be maintained such that the deflection of the ion beam 201 is improved. Besides, the real or actual implantation on the wafer 202 also can be adjusted accordingly. For example, the wafer 202 may be tilted to adjust the real-time incident angle on the wafer 202 such that the ion beam 201 is dynamically vertically implanted as predetermined.

Furthermore, with regard to the FIG. 2A depiction of the ion beam 201 being projected from beam entrance 223 through beam exit 222 and then along a desired trajectory to wafer 202 in an ideal condition, indeed, the deflected ion beam also passes through the beam exit 222. Therefore, the distribution of the conductive structures 225 can be divided into two cases: the distribution along a direction parallel to the desired trajectory, and the distribution on a cross-section of the beam exit vertical to the desired trajectory.

For example, some available variations of the first case are shown in FIGS. 2B-2D. Herein, FIG. 2B shows all conductive structures 225 being located only inside the beam exit 222, and FIG. 2C shows all conductive structures 225 being located outside the beam exit 222 and faced toward the wafer 201. FIG. 2D shows a configuration with all conductive structures 225 located around a portion of the shell 224. Note that a key or common concept to the variations is the monitoring and generation of different deflected angles of deflected ion beam 201 by use of conductive structure(s) 225.

The arrangement of FIG. 2B is capable of measuring a variable range of deflected angles (wherein larger widths of the conductive structure(s) 225 can facilitate measurement of larger deflected angles); the architecture of FIG. 2C is capable of measuring a variable range of deflected angles without reduction of the effective diameter of the beam exit 222 (wherein larger widths of the conductive structure(s) can facilitate measurement of larger deflected angles), and the design of FIG. 2D is capable of measuring a large range of deflected angles (wherein greater lengths of the conductive structure(s) 225 vertical to the desired trajectory can facilitate measurement of larger deflected angles).

The variation shown in FIG. 2C optionally can be modified to locate the conductive structures 225 outside the beam exit 222 and not overlap with a cross-section of the beam exit 222. Herein, the cross-section is vertical to the desired trajectory. Clearly, in this amendment, no conductive structure 225 is added into the beam exit 222, and then it is easier to locate the conductive structure(s) 225.

The variation shown in FIG. 2D can be modified optionally to locate the conductive structures 225 around a portion of the shell 224 partially overlapped with both a cross-section of the beam exit 222 and a portion of the shell 224 adjacent to the beam exit 222. Herein, the cross-section is vertical to the desired trajectory. Clearly, in this modification, the detectable defection angle can be increased simply by increasing the length of the conductive structures 225 overlapped with a portion of the shell 224.

For example, some variations of the second case are shown in FIGS. 2E-2G. Herein, FIG. 2E shows the conductive structure 225 as a single, one and only one, loop enclosing the desired trajectory. Herein, FIG. 2F shows a first conductive structure and a second structure oppositely disposed around the desired trajectory. Herein, FIG. 2G shows the conductive structures being numerous concentric arcs positioned around the desired trajectory.

Clearly, a key or underlying principle is the relative geometrical relation among the desired trajectory and the conductive structure(s) 225. By locating the conductive structure(s) 225 on or along one or more different angles/distances relative to the desired trajectory, the different deflections of the ion beam 201 can be detected. Owing to the ability of the ion beam 201 to be deflected to any direction, numerous conductive structures 225 typically can be located around the desired trajectory.

There are other non-shown variations. For example, the conductive structure(s) 225 can be located as an array or numerous concentric loops around the desired trajectory. As another example, because the conductive structure(s) 225 is used for the ion beam 201, the conductive structure(s) 225 can be at least one loop with a cross-sectional width briefly or about equal to a diameter of the ion beam, or one or more blocks separately distributed around the desired trajectory of the ion beam 201.

Note that the above variations are only examples. The invention can comprise any combination or permutation of any of the above variations/features and/or modifications to the above variations/features. For example, the above “all conductive structures 225” limitation can be replaced by “at least one conductive structure 225.” Furthermore, according to other implementations and aspects, any one or more of the characteristics of any one or more of the above variations/features can be mixed, in whole or in part, in any combination or permutation.

According to an aspect of the invention, the detailed location/shape/number of the conductive structure(s) 225 is not limited. Indeed, even the material of the conductive structure(s) 225 also is not limited. The practical shape, location, number and material of the conductive structure(s) 225 can be changed on a case-by-case basis. For instance, at least one conductive structure 225 can be made of a non-metal conductive material attached to shell 224. For example, the available conductive material for forming at least one conductive structure 225 can be graphite, conductive film, conductive glue, and so on.

In typical implementations, the shell 224 can be made of conductive material(s), such that ions with undesired charge and/or undesired mass are absorbed after collision with shell 224. Therefore, it is possible that the conductive structure(s) 225 is a portion of the shell 224. Of course, in such situations, the portion of shell 224 for collecting undesired ions and the portion of shell 224 for collecting defected ion beam 201 must be electrically insulated, such that the current measured by the measuring device 226 is induced only by the deflected ion beam 201.

In short, one main characteristic only is locating at least one conductive structure close to the boundary of the beam exit and electrically insulated from the shell, such that at least a portion of the deflected ion beam 201 can be detected before the deflected ion beam 201 is projected on the wafer 202.

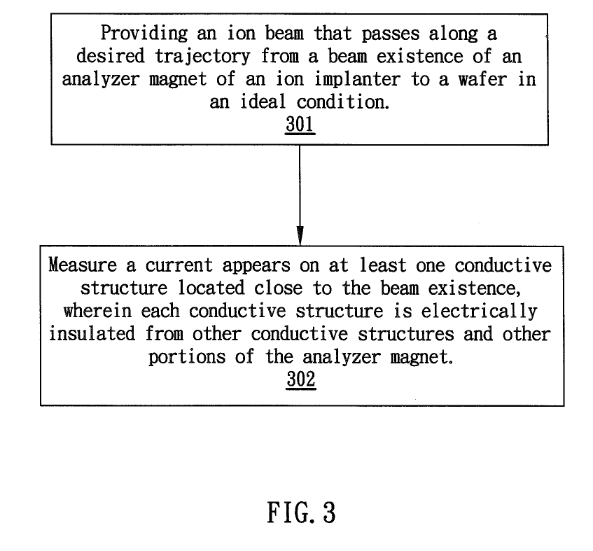

Another feature of the present invention is a method for real-time monitoring of an ion beam. Referring to FIG. 3, the method comprising the following steps: first, as shown in block 301, providing is an ion beam that passes along a desired trajectory from a beam exit of an analyzer magnet of an ion implanter to a wafer in an ideal condition; second, as shown in block 302, measurement is made of a current that appears on at least one conductive structure located close to the beam exit, wherein each conductive structure is electrically insulated from other conductive structures and other portions of the analyzer magnet. Of course, according to typical implementations, each conductive structure is electrically coupled with a measuring device for measuring the current.

Clearly, when the ion beam does not totally pass through the beam exit, some ions will collide with the conductive structure(s) and induce ion currents on the conductive structure(s). Hence, by real-time separately monitoring the ion current(s) of each conductive structure(s), owing to the general/basic operation and configuration of a conductive structure(s) that may be known, the real trajectory of the ion beam can be real-time monitored using the inventive conductive structure(s) according to the present disclosure.

Herein, according to certain aspects, the limitations and variations of the conductive structures are not key components of one or more of the disclosed embodiment(s). All of the limitations and variations discussed in the above embodiments can be applied to the embodiment(s).

Moreover, after the real (i.e., actual) trajectory of the ion beam is real-time monitored, the real (i.e., actual) implantation result on the wafer also can be real-time monitored. Therefore, it is possible to adjust at least one practical parameter value of one or more of the ion implanter or implantation process such that a real trajectory of the ion beam is adjusted to be, match, or better conform with the desired trajectory. It also is possible to maintain the ion implanter such that a real trajectory of the ion beam is adjusted to be, match, or better conform with the desired trajectory. Of course, if the cost/difficulty required to adjust the real trajectory is relatively high, it also is possible to adjust the geometric condition of the wafer such that an implantation result of the ion beam along a real trajectory is equal to or in better conformance with an implantation result of the ion beam along the desired trajectory.

Although specific embodiments have been illustrated and described, it will be appreciated by those skilled in the art that various modifications may be made without departing from the scope of the present invention, which is intended to be limited solely by the appended claims.

What is claimed is:

1. An ion implanter, comprising:
an ion source capable of generating an ion beam; and
an analyzer magnet capable of analyzing said ion beam, wherein said analyzer magnet has a shell, a beam entrance, a beam exit and at least one conductive structure, said beam entrance and beam exit being located on different portions of said shell, one or more of said at least one conductive structure being located close to a boundary of said exit and being electrically insulated from both said shell and any other ones of said at least one conductive structure;
wherein, each of one said at least one conductive structure is electrically coupled with a measuring device for measuring current independently of any other ones of said at least one conductive structure.

2. The ion implanter as set forth in claim 1, further comprising an isolation material disposed among each of said at least one conductive structure and said shell.

3. The ion implanter as set forth in claim 1, said at least one said conductive structure being a non-metal conductive material attached to said shell.

4. The ion implanter as set forth in claim 3, wherein said conductive material is chosen from a group consisting essentially of graphite, conductive film, conductive glue and combination thereof.

5. The ion implanter as set forth in claim 1, when said ion beam is projected from said beam exit along a desired trajectory to a wafer in an ideal condition, and a distribution of said at least one conductive structure along a direction parallel to said desired trajectory comprise one or more of:
at least one conductive structure located only inside said beam exit;
at least one conductive structure located outside said beam exit and faced toward said wafer; and
at least one conductive structure located around a portion of said shell.

6. The ion implanter as set forth in claim 5, wherein said at least one conductive structure located outside said beam exit is not overlapped with a cross-section of said beam exit, said cross-section being vertical to said desired trajectory.

7. The ion implanter as set forth in claim 5, wherein said at least one conductive structure located around a portion of said shell is totally overlapped with a cross-section of said beam exit, said cross-section being vertical to said desired trajectory.

8. The ion implanter as set forth in claim 5, wherein said at least one said conductive structure located around a portion of said shell is partially overlapped with a cross-section of said beam exit and a portion of said shell adjacent to said beam exit, said cross-section being vertical to said desired trajectory.

9. The ion implanter as set forth in claim 1, wherein, when said ion beam is projected from said beam exit along a desired trajectory to a wafer in an ideal condition, a distribution of said at least one conductive structure over a cross-section vertical to said desired trajectory comprises one or more of:
one and only one conductive structure shaped as a loop enclosing said desired trajectory; and
a plurality of conductive structures enclosing said desired trajectory.

10. The ion implanter as set forth in claim 9, wherein said conductive structure shaped as a loop comprises a cross-sectional width about equal to a diameter of said ion beam.

11. The ion implanter as set forth in claim 9, wherein the distribution of said at least one conductive structure around said desired trajectory comprises one or more of:
a first conductive structure and a second conductive structure opposingly disposed around said desired trajectory;
a plurality of concentric loops disposed around said desired trajectory;
an array disposed around said desired trajectory; and
a plurality of concentric arcs disposed around said desired trajectory.

12. A method for real-time monitoring of an ion beam, comprising:
providing an ion beam that in an ideal condition passes along a desired trajectory from a beam exit of an analyzer magnet of an ion implanter to a wafer; and
measuring a current appearing on at least one conductive structure located close to the beam exit;
wherein each one of said at least one conductive structure is electrically insulated from (i) any other ones of said at least one conductive structure and (ii) other portions of said analyzer magnet, wherein each of said at least one conductive structure is electrically coupled with a measuring device for measuring said current.

13. The method as set forth in claim 12, wherein at least one of said at least one conductive structure is made of a non-metal conductive material.

14. The method as set forth in claim 12, wherein a distribution of said at least one conductive structure along a direction parallel to said desired trajectory comprises one or more of:
at least one conductive structure located only inside said beam exit;
at least one conductive structure located outside said beam exit and faced toward said wafer; and
at least one conductive structure located around a portion of said shell.

15. The method as set forth in claim 12, further characterized by one or more of the following:
said at least one conductive structure being located outside said beam exit not overlapped with a cross-section of said beam exit, said cross-section being vertical to said desired trajectory;
said at least one conductive structure being located around a portion of said shell totally overlapped with a cross-section of said beam exit, said cross-section being vertical to said desired trajectory; and
said at least one conductive structure being located around a portion of said shell partially overlapped with a cross-section of said beam exit and a portion of said shell adjacent to said beam exit, said cross-section being vertical to said desired trajectory.

16. The method as set forth in claim 12, wherein a distribution of said at least one conductive structure over a cross-section vertical to said desired trajectory comprises:
one and only one conductive structure formed as a loop enclosing said desired trajectory; and
a plurality of conductive structures enclosing said desired trajectory.

17. The method as set forth in claim 16, wherein said distribution of said at least one conductive structure around said desired trajectory comprises:
a first block and a second block oppositely located around said desired trajectory;
a first conductive structure and a second conductive structure being opposingly located around said desired trajectory;
a plurality of concentric loops around said desired trajectory;
an array around said desired trajectory; and
a plurality of concentric arcs around said desired trajectory.

18. The method as set forth in claim 12, further comprising a step of adjusting at least one practical parameter value of said ion implanter such that an actual trajectory of said ion beam is adjusted to be said desired trajectory.

19. The method as set forth in claim 12, further comprising a step of maintaining said ion implanter such that an actual trajectory of said ion beam is adjusted to be said desired trajectory.

20. The method as set forth in claim 12, further comprising a step of adjusting a geometric condition of said wafer such that an implantation result of said ion beam along an actual trajectory is equal to an implantation result of said ion beam along said desired trajectory.
